(19) United States
(12) Patent Application Publication
(10) Pub. No.: US 2026/0157067 A1
(43) Pub. Date: Jun. 4, 2026

(54) DISPLAY DEVICE AND ELECTRONIC DEVICE

(71) Applicant: Samsung Display Co., Ltd., Yongin-si (KR)

(72) Inventors: MINKYU JI, Yongin-si (KR); Jaebum CHO, Yongin-si (KR); KWANG-HYUN KIM, Yongin-si (KR); JOUNG-KEUN PARK, Yongin-si (KR); JUKI PARK, Yongin-si (KR); CHAN HYUK PARK, Yongin-si (KR); NAM-WOOK LEE, Yongin-si (KR)

(21) Appl. No.: 19/177,419

(22) Filed: Apr. 11, 2025

(30) Foreign Application Priority Data
Jun. 19, 2024 (KR) 10-2024-0079903

(51) Int. Cl. H10K 59/35

(52) U.S. Cl. CPC H10K 59/353

(57) ABSTRACT

Provided is a display device including a display region including a plurality of unit pixels and a non-display region adjacent to the display region, wherein each of the plurality of unit pixels includes at least one pixel region and a transmission region which is adjacent to the pixel region and through which external light is transmitted, and for each of the plurality of unit pixels, the ratio of the area of the transmission region to the area of the unit pixel is between about 50% and about 73%.

### CROSS-REFERENCE TO RELATED APPLICATION

The present application claims priority to and the benefit of Korean Patent Application No. 10-2024-0079903, filed on Jun. 19, 2024, the entire content of which is hereby incorporated by reference.

### BACKGROUND

Embodiments of the present disclosure herein relate to a display device, and, for example, to a transparent display device having improved clarity and diffraction characteristics of transmitted light.

Various suitable multimedia electronic devices such as, for example, televisions, mobile phones, tablet computers, and game consoles include a display panel and a light conversion panel to provide image information to users.

The display panel includes a light-emitting element and a pixel driving circuit to drive the light-emitting element. The light conversion panel may include a light control unit which uses quantum dots, and source light provided from the display panel may be converted by the light control unit and provided as multi-colored light. The light conversion panel includes a color filter, and the color filter improves the color purity and light extraction efficiency of the multi-colored light and reduces the reflection of external light.

Recently, transparent display devices including a transmission region within a display region are being developed. Research is needed to improve the light transmission characteristics of the transparent display devices.

### SUMMARY

Embodiments of the present disclosure provide a transparent display device having improved clarity and diffraction characteristics of transmitted light.

An embodiment of the present disclosure provides a display device including a display region including a plurality of unit pixels and a non-display region adjacent to the display region, wherein each of the plurality of unit pixels includes at least one pixel region and a transmission region which is adjacent to the pixel region and through which external light is transmitted, and for each of the plurality of unit pixels, the ratio of the area of the transmission region to the area of the unit pixel is between about 50% and about 73%.

In an embodiment, the planar shape of the transmission region may be oval (e.g., may have a generally oval shape).

In an embodiment, the planar shape of the transmission region may be circular (e.g., may be generally circular).

In an embodiment, each of the plurality of unit pixels may include a first pixel region that emits a first light; a second pixel region that emits a second light having a wavelength different from the wavelength of the first light; and a third pixel region that emits a third light having a wavelength different from the wavelengths of the first light and the second light.

In an embodiment, each of the first to third pixel regions may be provided alternately with the transmission region along a first direction.

In an embodiment, the first to third pixel regions may be provided sequentially and alternately along a second direction perpendicular (e.g., substantially perpendicular) to the first direction.

In an embodiment, each of the first and second pixel regions may be provided alternately with the transmission region along a first direction.

In an embodiment, each of the first and second pixel regions may be provided alternately with the third pixel region along the first direction.

In an embodiment, the first and second pixel regions may be provided alternately along a second direction perpendicular (e.g., substantially perpendicular) to the first direction.

In an embodiment of the present disclosure, a display device includes a display region including a plurality of unit pixels and a non-display region adjacent to the display region, wherein each of the plurality of unit pixels includes at least one pixel region and a transmission region which is adjacent to the pixel region and through which external light is transmitted, wherein the planar shape of the transmission region is circular (e.g., generally circular) or oval (e.g., generally an oval shape).

In an embodiment, for each of the plurality of unit pixels, a ratio of an area of the transmission region to an area of the unit pixel may be between about 50% and about 73%.

In an embodiment, each of the plurality of unit pixels may include a first pixel region that emits a first light; a second pixel region that emits a second light having a wavelength different from the wavelength of the first light; and a third pixel region that emits a third light having a wavelength different from the wavelengths of the first light and the second light.

In an embodiment, each of the first to third pixel regions may be provided alternately with the transmission region along a first direction.

In an embodiment, the first to third pixel regions may be provided sequentially and alternately along a second direction perpendicular (e.g., substantially perpendicular) to the first direction.

In an embodiment, each of the first and second pixel regions may be provided alternately with the transmission region along a first direction.

In an embodiment, each of the first and second pixel regions may be provided alternately with the third pixel region along the first direction.

In an embodiment, the first and second pixel regions may be provided alternately along a second direction perpendicular (e.g., substantially perpendicular) to the first direction.

In an embodiment of the present disclosure, an electronic device includes: a display device, a window on the display device, and a housing under the display device, wherein the display device includes: a display panel including a unit pixel including a plurality of pixel regions and a transmission region adjacent to the plurality of pixel regions; and a light conversion panel on the display panel, wherein the light conversion panel includes a color filter layer, wherein the color filter layer may include an opening defining the transmission region, and the planar shape of the opening may be circular (e.g., generally circular) or oval (e.g., a generally oval shape).

In an embodiment, the plurality of pixel regions may be provided alternately with the transmission region along a first direction.

In an embodiment, based on the area of the unit pixel, the area of the opening may be between about 50% and about 73%.

### BRIEF DESCRIPTION OF THE DRAWINGS

The accompanying drawings are included to provide a further understanding of the subject matter of the present disclosure, and are incorporated in and constitute a part of this specification. The drawings illustrate embodiments of the present disclosure and, together with the description, serve to explain principles of the present disclosure. In the drawings:

FIG. 1A is a perspective view of a display device according to an embodiment of the present disclosure;

FIG. 1B is a cross-sectional view of the display device according to an embodiment of the present disclosure;

FIG. 2 is a plan view of a display panel according to an embodiment of the present disclosure;

FIG. 3 is an equivalent circuit diagram of a pixel according to an embodiment of the present disclosure;

FIG. 4A is an enlarged plan view of a display region according to an embodiment of the present disclosure;

Each of FIGS. 4B to 4D is an enlarged plan view of the display region according to another embodiment of the present disclosure;

FIG. 5 is a cross-sectional view of the display device according to an embodiment of the present disclosure;

FIGS. 6A and 6B are cross-sectional views of light-emitting layers according to an embodiment of the present disclosure;

FIG. 7 is a cross-sectional view of the display device according to an embodiment of the present disclosure;

FIGS. 8A and 8B are clarity evaluation images according to an embodiment of the present disclosure and a comparative embodiment of the present disclosure, respectively.

FIGS. 9A and 9B are clarity evaluation graphs according to an embodiment of the present disclosure and a comparative embodiment of the present disclosure, respectively;

FIGS. 10A and 10B are a clarity evaluation photograph and an enlarged photograph thereof according to an embodiment of the present disclosure, respectively;

FIGS. 10C and 10D are a clarity evaluation photograph and an enlarged photograph thereof according to a comparative embodiment of the present disclosure, respectively;

FIGS. 11A and 11B are images evaluating diffraction characteristics according to an embodiment of the present disclosure and a comparative embodiment of the present disclosure, respectively;

FIG. 12 is a graph showing the results of evaluating the luminous efficiency of the display device according to aperture ratios; and

FIGS. 13A and 13B are clarity evaluation images according to an embodiment of the present disclosure and a comparative embodiment of the present disclosure, respectively.

FIG. 14A is a perspective view of an electronic device according to an embodiment of the disclosure.

FIG. 14B is an exploded perspective view of the electronic device according to an embodiment of the disclosure.

### DETAILED DESCRIPTION

In embodiments of the present disclosure, various suitable modifications can be made, various suitable forms can be used, and example embodiments will be illustrated in the drawings and described in more detail in the text. However, this is not intended to limit the present disclosure to a specific form disclosed, and it will be understood that all changes, equivalents, or substitutes which fall in the spirit and technical scope of the present disclosure should be included.

In this specification, singular expressions include plural expressions unless clearly specified otherwise by the context.

In this specification, it will be understood that the terms “include” and/or “have”, when used in this specification, specify the presence of stated features, integers, steps, operations, elements, components and/or groups thereof, but do not preclude the presence or addition of one or more other features, integers, steps, operations, elements, components, and/or groups thereof.

In this specification, it will be understood that when an element (or region, layer, portion, and/or the like) is referred to as being “on”, “connected to” or “coupled to” another element, it can be directly on, connected or coupled to the other element, or intervening elements may be present.

In this specification, terms, such as “below”, “lower”, “above”, “upper” and the like, are used herein for ease of description to describe one element's relation to another element(s) as illustrated in the figures. The above terms are relative concepts and are described based on the directions indicated in the drawings.

In this specification, “being on” may refer to being not only on the top but also on the bottom of a member.

In this specification, “being directly on” may mean that there is no layer, film, region, plate, or the like added between a part such as a layer, film, region, or plate and another part such as a layer, film, region, or plate. For example, “being directly on” may mean that no additional member such as an adhesive member is between two layers or two members.

In this specification, the term “and/or” includes any and all combinations that the associated configurations can define

In this specification, it will be understood that, although the terms first, second, and/or the like may be used herein to describe various elements, these elements should not be limited by these terms. These terms are only used to distinguish one element from another element. For example, a first element could be termed a second element without departing from the scope of the present disclosure. Similarly, the second element may also be referred to as the first element.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Like reference numerals refer to like elements throughout. In embodiments, in the drawings, the thicknesses, ratios, and dimensions of elements may be exaggerated for effective description of the technical contents.

Hereinafter, a display device according to an embodiment of the present disclosure will be described with reference to the accompanying drawings.

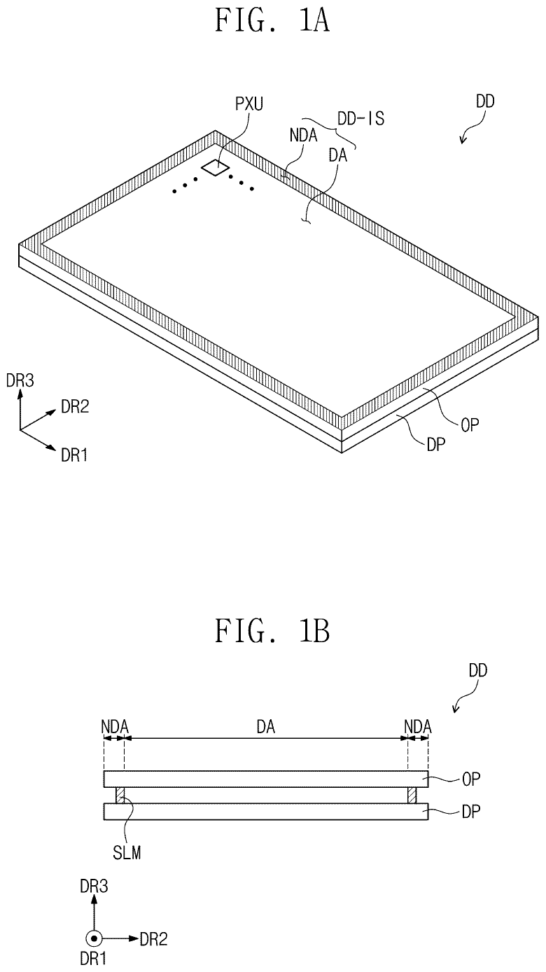

FIG. 1A is a perspective view of a display device DD according to an embodiment of the present disclosure. FIG. 1B is a cross-sectional view of the display device DD according to an embodiment of the present disclosure.

Referring to FIG. 1A, the display device DD may display an image through a display surface DD-IS. The display surface DD-IS may be parallel to a plane defined by a first direction DR1 and a second direction DR2. The upper surface of a member on the uppermost side of the display device DD in a third direction DR3 may be defined as the display surface DD-IS.

The normal direction of the display surface DD-IS, for example, the thickness direction of the display device DD, may be indicated by the third direction DR3. The front (or upper) and rear (or lower) surfaces of each layer or unit described below may be divided by the third direction DR3.

The display device DD may include a display region DA and a non-display region NDA. Unit pixels PXU are provided in the display region DA, and the unit pixels PXU are not provided in the non-display region NDA. The non-display region NDA may be defined along the border of the display surface DD-IS. The non-display region NDA may surround the display region DA. In an embodiment of the present disclosure, the non-display region NDA may be omitted or provided only on one side of the display region DA. Although a planar display device DD is illustrated as an example in FIG. 1A, the display device DD may have a curved shape and/or may be capable of being folded, rolled, and/or slid from a housing.

A unit pixel PXU illustrated in FIG. 1A may define a pixel row and a pixel column. As a minimum repeating unit, the unit pixel PXU may include at least one pixel. The unit pixel PXU may include a plurality of pixels that provide light of different colors.

Referring to FIG. 1B, the display device DD may include a display panel DP and a light conversion panel OP which faces and is spaced apart from the display panel DP. The display panel DP may be referred to as a lower display substrate, and the light conversion panel OP may be referred to as an upper display substrate. A cell gap may be formed between the display panel DP and the light conversion panel OP. The cell gap may be maintained by a sealing member SLM that couples the display panel DP and the light conversion panel OP to each other. The sealing member SLM may include a binder resin and inorganic fillers mixed with the binder resin. The sealing member SLM may further include other additives. The additives may include an amine-based curing agent and a photoinitiator. The additives may further include a silane-based additive and an acrylic-based additive. The sealing member SLM may include an inorganic-based material such as, for example, frit.

In each of the display panel DP and the light conversion panel OP, a display region DA and a non-display region NDA may be defined so as to correspond to the display region DA and the non-display region NDA of the display device DD. Hereinafter, the display region DA of the display device DD may refer to the display region DA of each of the display panel DP and the light conversion panel OP, and the non-display region NDA of the display device DD may refer to the non-display region NDA of each of the display panel DP and the light conversion panel OP.

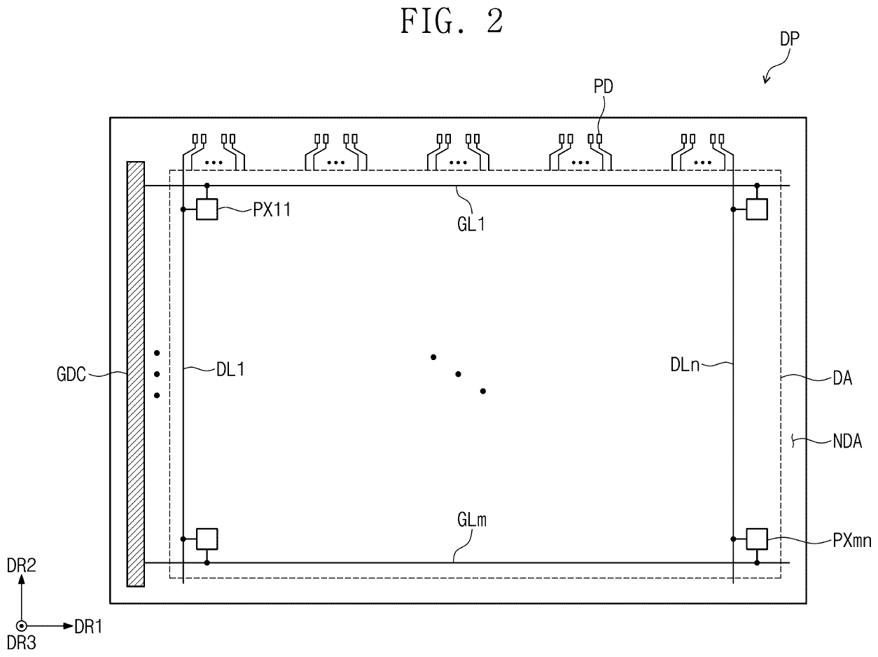

FIG. 2 is a plan view of a display panel DP according to an embodiment of the present disclosure.

FIG. 2 illustrates the planar arrangement relationship of signal lines GL1 to GLm and DL1 to DLn and pixels PX11 to PXmn. The signal lines GL1 to GLm and DL1 to DLn may include a plurality of gate lines GL1 to GLm and a plurality of data lines DL1 to DLn.

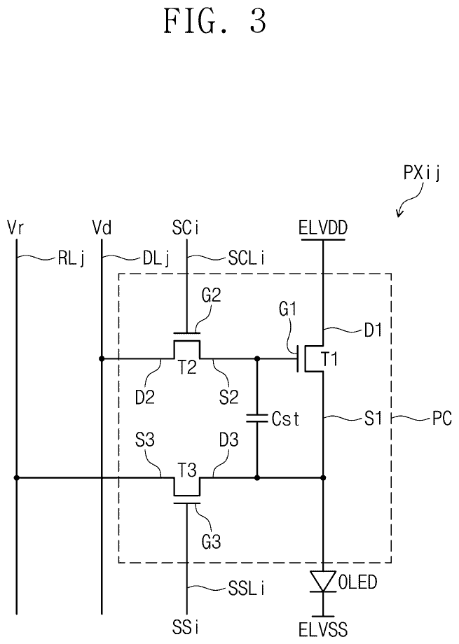

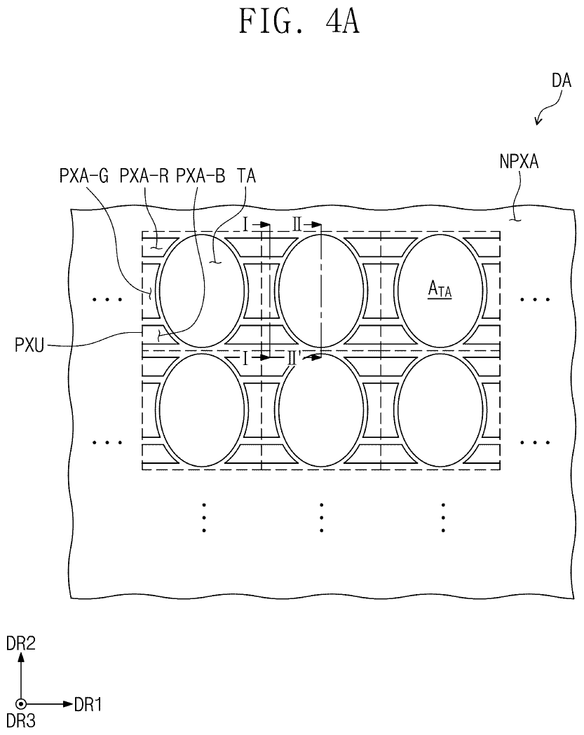

Each of the pixels PX11 to PXmn may be connected to a corresponding gate line among the plurality of gate lines GL1 to GLm and a corresponding data line among the plurality of data lines DL1 to DLn. Each of the pixels PX11 to PXmn may include a pixel driving circuit and a light-emitting element. Depending on the configuration of the pixel driving circuits of the pixels PX11 to PXmn, more types (or kinds) of signal lines may be provided in the display panel DP. For example, each of the gate lines GL1 to GLm may include a corresponding scan line SCLi (see FIG. 3) and a corresponding sensing line SSLi (see FIG. 3).

A gate driver circuit GDC may be integrated into the display panel DP through an oxide semiconductor gate driver circuit (OSG) process or an amorphous silicon gate driver circuit (ASG) process. The gate driving circuit GDC connected to the gate lines GL1 to GLm may be on one side of the non-display region NDA in the first direction DR1. Pads PD connected to the ends of the plurality of data lines DL1 to DLn may be on one side of the non-display region NDA in the second direction DR2.

FIG. 3 is an equivalent circuit diagram of a pixel PXij according to an embodiment of the present disclosure.

FIG. 3, as an example, illustrates the pixel PXij connected to an i-th scan line SCLi, an i-th sensing line SSLi, a j-th data line DLj, and a j-th reference line RLj. The pixel PXij may include a pixel circuit PC and a light-emitting element OLED connected to the pixel circuit PC. The pixel circuit PC may include a plurality of transistors T1, T2, and T3 and a capacitor Cst. The plurality of transistors T1, T2, and T3 may be formed through a low temperature polycrystalline silicon (LTPS) process or a low temperature polycrystalline oxide (LTPO) process. Hereinafter, the plurality of transistors T1, T2, and T3 are described as N-type transistors, but at least one transistor may be implemented as a P-type transistor.

In this embodiment, the pixel circuit PC including a first transistor T1, a second transistor T2, a third transistor T3, and a capacitor Cst is illustrated as an example, but the pixel circuit PC is not limited thereto. The first transistor T1 may be a driving transistor, the second transistor T2 may be a switching transistor, and the third transistor T3 may be a sensing transistor. The pixel circuit PC may further include an additional transistor and/or an additional capacitor.

The light-emitting element OLED may be an organic light-emitting element or an inorganic light-emitting element which includes an anode (first electrode) and a cathode (second electrode). The anode of the light-emitting element OLED may receive a first voltage ELVDD through the first transistor T1, and the cathode of the light-emitting element OLED may receive a second voltage ELVSS. The light-emitting element OLED may emit light by receiving the first voltage ELVDD and the second voltage ELVSS.

The first transistor T1 may include a drain D1 configured to receive the first voltage ELVDD, a source S1 connected to the anode of the light-emitting element OLED, and a gate G1 connected to the capacitor Cst. The first transistor T1 may control a driving current flowing from the first voltage ELVDD to the light-emitting element OLED in response to a voltage value stored in the capacitor Cst.

The second transistor T2 may include a drain D2 connected to the j-th data line DLj, a source S2 connected to the capacitor Cst, and a gate G2 configured to receive an i-th first scan signal SCi. The j-th data line DLj may receive a data voltage Vd. The second transistor T2 may provide the data voltage Vd to the first transistor T1 in response to the i-th first scan signal SCi.

The third transistor T3 may include a source S3 connected to the j-th reference line RLj, a drain D3 connected to the anode of the light-emitting element OLED, and a gate G3 configured to receive an i-th second scan signal SSi. The j-th reference line RLj may receive a reference voltage Vr. The third transistor T3 may initialize the capacitor Cst and the anode of the light-emitting element OLED.

The capacitor Cst may store a voltage corresponding to a difference between a voltage received from the second transistor T2 and the first voltage ELVDD. The capacitor Cst may be connected to the gate G1 of the first transistor T1 and the anode of the light-emitting element OLED.

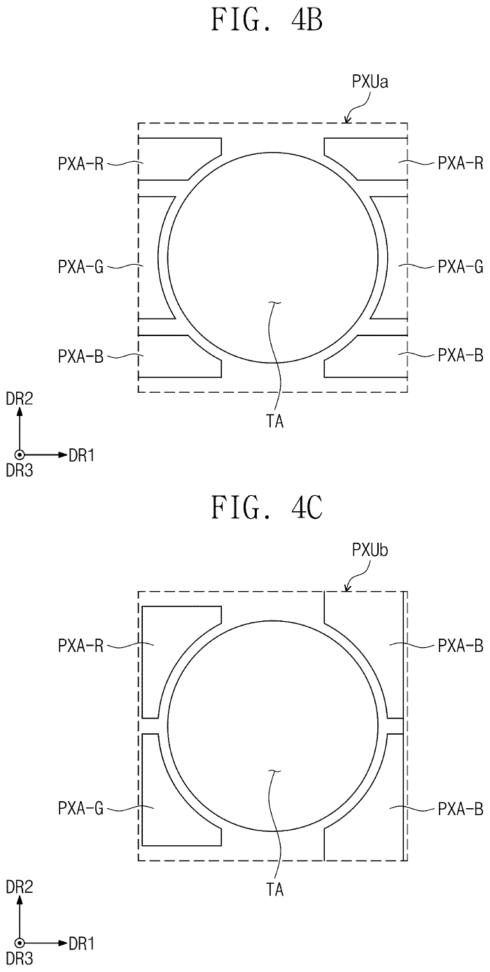

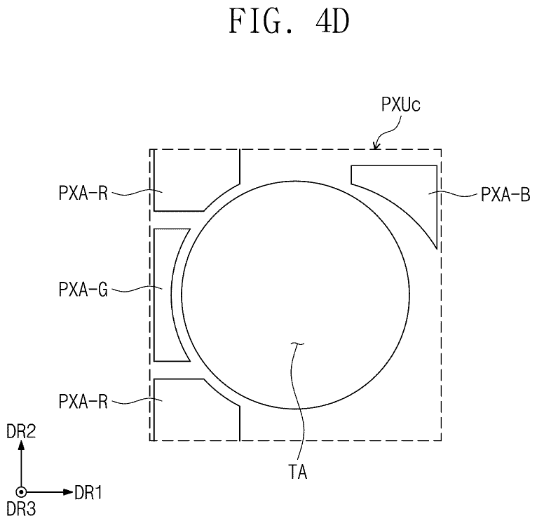

FIG. 4A is an enlarged plan view of a display region DA according to an embodiment of the present disclosure. Each of FIGS. 4B to 4D is an enlarged plan view of the display region DA (see FIG. 4A) according to another embodiment of the present disclosure. For example, each of FIGS. 4B to 4D illustrates another embodiment of the unit pixel PXU of FIG. 4A.

As illustrated in FIG. 4A, the unit pixels PXU may be provided in the first direction DR1 and the second direction DR2, respectively. In this embodiment, the unit pixel PXU may include a first pixel, a second pixel, and a third pixel that emit light of different colors. Red light, green light, and blue light may be output from the first pixel, the second pixel, and the third pixel, respectively. In FIG. 4A, a first pixel region PXA-R, a second pixel region PXA-G, and a third pixel region PXA-B respectively representing the first pixel, the second pixel, and the third pixel are illustrated. The first pixel region PXA-R may be a region in which light generated by the first pixel is provided to the outside, the second pixel region PXA-G may be a region in which light generated by the second pixel is provided to the outside, and the third pixel region PXA-B may be a region in which light generated by the third pixel is provided to the outside.

A peripheral region NPXA may surround the first pixel region PXA-R, the second pixel region PXA-G, and the third pixel region PXA-B. In embodiments, the peripheral region NPXA may be between the first pixel region PXA-R, the second pixel region PXA-G, and the third pixel region PXA-B. The peripheral region NPXA may set the boundaries of the first to third pixel regions PXA-R, PXA-G, and PXA-B and prevent or reduce color mixing between the first to third pixel regions PXA-R, PXA-G, and PXA-B.

The first pixel region PXA-R, the second pixel region PXA-G, and the third pixel region PXA-B may be spaced apart from each other along the second direction DR2. In the planar shapes of the first pixel region PXA-R, the second pixel region PXA-G, and the third pixel region PXA-B of FIG. 4A, the shape of a boundary extending in the first direction DR1 is illustrated as being a straight line and the shape of a boundary adjacent to a transmission region TA is illustrated as being a curve that corresponds to the shape of a boundary of the transmission region TA which will be further described herein, but this is an example and embodiments of the present disclosure are not limited thereto.

The unit pixel PXU may include a transmission region TA spaced apart from each of the first pixel region PXA-R, the second pixel region PXA-G, and the third pixel region PXA-B in the first direction DR1. The transmission region TA may have a higher light transmittance than the first pixel region PXA-R, the second pixel region PXA-G, and the third pixel region PXA-B. The display device DD (see FIG. 1) may be implemented as a transparent display device as the transmission region TA is provided in the display region DA. In embodiments, the transparent display device may refer to a display device that allows a user to recognize an image displayed by light emitted from the light-emitting elements of the display device while concurrently (e.g., simultaneously) recognizing light passing through the display device via the transmission region TA. The terms “transmitting light” and “transmitted light” may refer to light that is emitted from a light source on the opposite side of a user based on a display device or reflected from an object and then passes through the display device.

Based on the area of the unit pixel PXU, an area A_{TA} of the transmission region TA may be between about 50% and about 73%. When the area A_{TA} of the transmission region TA is less than about 50%, the clarity of the transmitted light may be low. When the area A_{TA} of the transmission region TA is more than about 73%, the luminous efficiency of the display device DD (see FIG. 1A) may be low.

The planar shape of the transmission region TA may be oval (e.g., generally an oval shape) or circular (e.g., generally circular). As the planar shape of the transmission region TA is oval (e.g., a generally an oval shape) or circular (e.g., generally circular), the diffraction characteristics of transmitted light may be improved compared to a polygonal shape. FIG. 4A illustrates, as an example, an embodiment in which the planar shape of the transmission region TA is oval. The planar shape of the transmission region TA may be an oval having a diameter in the second direction DR2 larger than a diameter thereof in the first direction DR1.

Referring to unit pixels PXUa, PXUb, and PXUc of FIGS. 4B to 4D, the planar shape of the transmission region TA may be circular. For example, the diameter thereof in the first direction DR1 and the diameter thereof in the second direction DR2 may be substantially the same as each other. In embodiments, being substantially the same as each other may mean that they are considered to be the same as each other even though there is an error that may occur during a process. In embodiments, the planar shape of the transmission region TA may be an oval (e.g., substantially an oval) having a diameter thereof in the first direction DR1 larger than a diameter thereof in the second direction DR2.

Referring to FIGS. 4A and 4B, each of the first to third pixel regions PXA-R, PXA-G, and PXA-B may be provided alternately with the transmission region TA in the first direction DR1. In embodiments, the first to third pixel regions PXA-R, PXA-G, and PXA-B may be provided sequentially and alternately in the second direction DR2.

Referring to FIGS. 4C and 4D, each of the first and second pixel regions PXA-R and PXA-G may be provided alternately with the third pixel region PXA-B in the first direction DR1. For example, the first and second pixel regions PXA-R and PXA-G may be provided at a position adjacent to one transmission region TA in a direction opposite to the first direction DR1, and the third pixel region PXA-B may be provided adjacent to the transmission region TA in the first direction DR1. The first and second pixel regions PXA-R and PXA-G may be provided sequentially and alternately in the second direction DR2. The third pixel regions PXA-B may be provided in the second direction DR2.

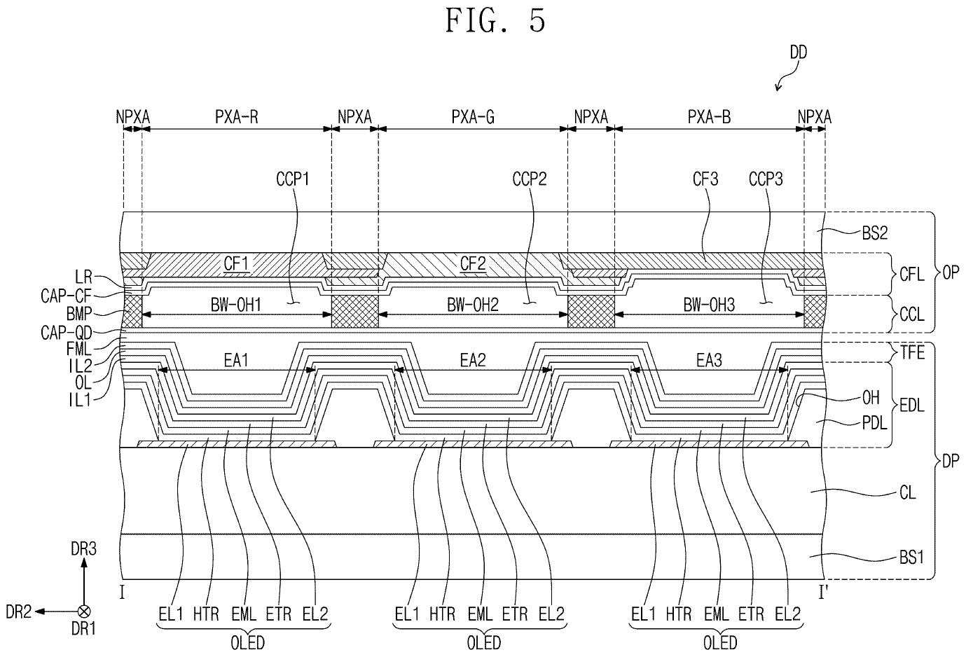

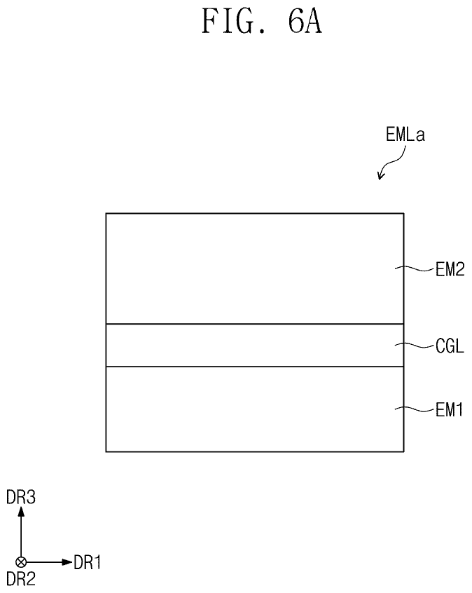

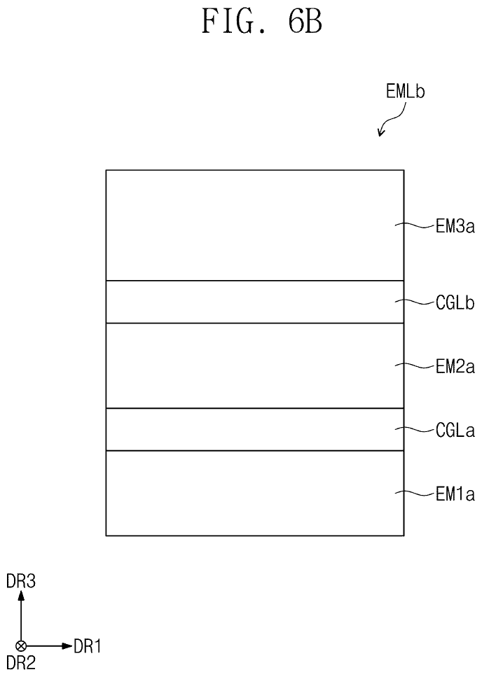

FIG. 5 is a cross-sectional view of the display device DD according to an embodiment of the present disclosure. FIGS. 6A and 6B are cross-sectional views of light-emitting layers EMLa and EMLb, respectively, according to an embodiment of the present disclosure.

FIG. 5 illustrates a cross section corresponding to line I-I′ illustrated in FIG. 4A.

Referring to FIG. 5, the display panel DP may include a first base layer BS1, a circuit layer CL, a light-emitting element layer EDL, and a thin film encapsulation layer TFE. The circuit layer CL may be on the first base layer BS1. The light-emitting element layer EDL may be on the circuit layer CL. The thin film encapsulation layer TFE may be on and seal the light-emitting element layer EDL.

The first base layer BS1 may include glass and/or a synthetic resin film. The synthetic resin layer may include a thermosetting resin. In embodiments, the synthetic resin layer may be a polyimide-based resin layer, and the material thereof is not particularly limited. The synthetic resin layer may include at least any one of an acrylic-based resin, a methacrylic-based resin, polyisoprene, a vinyl-based resin, an epoxy-based resin, a urethane-based resin, a cellulose-based resin, a siloxane-based resin, a polyamide-based resin, or a perylene-based resin. In embodiments, the first base layer BS1 may include a glass substrate, a metal substrate, and/or an organic/inorganic composite material substrate.

The circuit layer CL may be on the first base layer BS1. The circuit layer CL may include an insulating layer (e.g., an electrically insulating layer), a semiconductor pattern, a conductive pattern (e.g., an electrically conductive pattern), a signal line, and/or the like. An insulating layer (e.g., an electrically insulating layer), a semiconductor layer, and a conductive layer (e.g., an electrically conductive layer) may be formed on the first base layer BS1 by a method such as coating and/or deposition, and then the insulating layer, the semiconductor layer, and the conductive layer may be selectively patterned through a plurality of photolithography processes. Accordingly, the semiconductor pattern, the conductive pattern, and the signal line may be formed in the circuit layer CL. The circuit layer CL may include a transistor, a buffer layer, and a plurality of insulating layers (e.g., electrically insulating layers).

The light-emitting element layer EDL may be on the circuit layer CL and include a light-emitting element OLED and a pixel defining film PDL.

The light-emitting element OLED may include a first electrode EL1, a second electrode EL2 facing the first electrode EL1, and a light-emitting layer EML between the first electrode EL1 and the second electrode EL2. The light-emitting layer EML included in the light-emitting element OLED may include an organic light-emitting material and/or a quantum dot as a light-emitting material. The light-emitting element OLED may further include a hole transport region HTR and/or an electron transport region ETR. In embodiments, the light-emitting element OLED may further include a capping layer on the second electrode EL2.

The pixel defining film PDL may be on the circuit layer CL and cover a portion of the first electrode EL1. A light-emitting opening OH may be defined in the pixel defining film PDL. The light-emitting opening OH of the pixel defining film PDL exposes at least a portion of the first electrode EL1. First to third light-emitting regions EA1, EA2, and EA3 may be defined to correspond to a portion of the first electrode EL1 exposed by the light-emitting opening OH of the pixel defining film PDL. The first light-emitting region EA1, the second light-emitting region EA2, and the third light-emitting region EA3 may correspond to the first pixel region PXA-R, the second pixel region PXA-G, and the third pixel region PXA-B, respectively. A region excluding the first to third light-emitting regions EA1, EA2, and EA3 may be defined as a non-light-emitting region.

In this specification, the expression “one component corresponds to another component” means that the two components overlap each other when viewed in the thickness direction DR3 of the display device DD and is not limited to a same area. The first to third light-emitting regions EA1, EA2, and EA3 may overlap the first to third pixel regions PXA-R, PXA-G, and PXA-B, respectively. When viewed on a plane, the areas of the first to third pixel regions PXA-R, PXA-G, and PXA-B may be larger than the areas of the first to third light-emitting regions EA1, EA2, and EA3 divided by the pixel defining film PDL. However, this is only an example, and embodiments of the present disclosure are not limited thereto. The areas of the pixel regions PXA-R, PXA-G, and PXA-B may be substantially the same as the areas of the light-emitting regions EA1, EA2, and EA3 divided by the pixel defining film PDL.

The first electrode EL1 may be on the circuit layer CL. The first electrode EL1 may be an anode or a cathode. In embodiments, the first electrode EL1 may be a pixel electrode. The first electrode EL1 may be a transmissive electrode, a semi-transmissive electrode, or a reflective electrode.

The hole transport region HTR may be on the first electrode EL1. The hole transport region HTR may be commonly provided in the first to third light-emitting regions EA1, EA2, and EA3 and the non-light-emitting region. A common layer such as the hole transport region HTR may overlap a plurality of unit pixels PXU in the display region DA illustrated in FIG. 4A. However, embodiments of the present disclosure are not limited thereto, and the hole transport region HTR may be separately provided to correspond to each of the first to third light-emitting regions EA1, EA2, and EA3. The hole transport region HTR may include at least one of a hole transport layer, a hole injection layer, or an electron blocking layer.

The light-emitting layer EML may be on the hole transport region HTR. The light-emitting layer EML may be commonly provided in the first to third light-emitting regions EA1, EA2, and EA3 and the non-light-emitting region. The light-emitting layer EML may entirely overlap the hole transport region HTR and the electron transport region ETR. However, embodiments of the present disclosure are not limited thereto, and in an embodiment of the present disclosure, the light-emitting layer EML may be provided in the light-emitting opening OH. For example, the light-emitting layer EML may be separately provided to correspond to each of the first to third light-emitting regions EA1, EA2, and EA3 divided by the pixel defining film PDL.

The light-emitting layer EML may generate source light. In an embodiment of the present disclosure, the light-emitting layer EML may emit blue light. In the display device DD according to an embodiment of the present disclosure, the blue light may be the source light. When the light-emitting layer EML is separately provided to correspond to the first to third light-emitting regions EA1, EA2, and EA3, the separated light-emitting layers EML may all emit blue light or may respectively emit light of different wavelength ranges in the first to third light-emitting regions EA1, EA2, and EA3.

The light-emitting layer EML may have a single layer made of a single material, a single layer made of a plurality of different materials, or a multi-layered structure having a plurality of layers made of a plurality of different materials. The light-emitting layer EML may include a fluorescent and/or phosphorescent material. In the light-emitting element according to an embodiment of the present disclosure, the light-emitting layer EML may include an organic light-emitting material, a metal organic complex, and/or a quantum dot as a light-emitting material.

FIGS. 6A and 6B are cross-sectional views, as examples, illustrating a case in which the above-described light-emitting layer EML (see FIG. 5) has a multi-layered structure.

Referring to FIG. 6A, the light-emitting layer EMLa may include a first light-emitting layer EM1, a charge generation layer CGL, and a second light-emitting layer EM2 which are sequentially stacked along the third direction DR3. The first light-emitting layer EM1 and the second light-emitting layer EM2 may emit light of different colors. For example, the first light-emitting layer EM1 may emit blue light, and the second light-emitting layer EM2 may emit green light.

The charge generation layer CGL may be between the first light-emitting layer EM1 and the second light-emitting layer EM2. The charge generation layer CGL may supply electrons or holes to each of the first and second light-emitting layers EM1 and EM2, thereby being able to improve luminous efficiency.

Referring to FIG. 6B, the light-emitting layer EMLb may include a first light-emitting layer EM1a, a first charge generation layer CGLa, a second light-emitting layer EM2a, a second charge generation layer CGLb, and a third light-emitting layer EM3a which are sequentially stacked along the third direction DR3.

One of the first light-emitting layer EM1a, the second light-emitting layer EM2a, and the third light-emitting layer EM3a may emit light of a color different from those of the others. For example, the first light-emitting layer EM1a and the third light-emitting layer EM3a may emit light of a same color, and the second light-emitting layer EM2a may emit light of a color different from that of light generated by the first light-emitting layer EM1a. For example, the first light-emitting layer EM1a and the third light-emitting layer EM3a may emit blue light, and the second light-emitting layer EM2a may emit green light.

The first charge generation layer CGLa may be between the first light-emitting layer EM1a and the second light-emitting layer EM2a. The second charge generation layer CGLb may be between the second light-emitting layer EM2a and the third light-emitting layer EM3a. The first charge generation layer CGLa may supply electrons or holes to each of the first and second light-emitting layers EM1a and EM2a, thereby being able to improve luminous efficiency. In embodiments, the second charge generation layer CGLb may supply electrons or holes to each of the second light-emitting layer EM2a and the third light-emitting layer EM3a, thereby being able to improve luminous efficiency.

Referring again to FIG. 5, the electron transport region ETR may be disposed on the light-emitting layer EML. The electron transport region ETR may include at least one of an electron injection layer, an electron transport layer, or a hole blocking layer. The electron transport region ETR may be provided as a common layer to entirely overlap the first to third light-emitting regions EA1, EA2, and EA3 and the pixel defining film PDL. However, embodiments of the present disclosure are not limited thereto, and the electron transport region ETR may be separately provided to correspond to each of the first to third light-emitting regions EA1, EA2, and EA3.

The second electrode EL2 may be on the electron transport region ETR. The second electrode EL2 may be a common electrode. The second electrode EL2 may be a cathode or an anode, but embodiments of the present disclosure are not limited thereto. For example, when the first electrode EL1 is an anode, the second electrode EL2 may be a cathode, and when the first electrode EL1 is a cathode, the second electrode EL2 may be an anode. The second electrode EL2 may be a transmissive electrode, a semi-transmissive electrode, or a reflective electrode.

The thin film encapsulation layer TFE may be on the second electrode EL2. In embodiments, when the light-emitting element OLED includes a capping layer, the thin film encapsulation layer TFE may be disposed on the capping layer. The thin film encapsulation layer TFE may protect the light-emitting element layer EDL from moisture and oxygen and prevent or reduce entrance of foreign substances such as dust particles.

The thin film encapsulation layer TFE may include at least one inorganic film IL1 or IL2. The inorganic film IL1 or IL2 may include at least one of silicon nitride, silicon oxy nitride, silicon oxide, titanium oxide, or aluminum oxide. The thin film encapsulation layer TFE may include at least one organic film OL. The organic film OL may include an organic polymer material formed from an acrylate-based resin and/or the like. However, this is an example, and embodiments of the present disclosure are not limited thereto.

The light conversion panel OP may be on the display panel DP. The light conversion panel OP may include a second base layer BS2, a color filter layer CFL, and a light control layer CCL. The color filter layer CFL may be below the second base layer BS2. The light control layer CCL may be below the color filter layer CFL.

The second base layer BS2 may be a member that provides a base surface on which the color filter layer CFL or the like is provided. The second base layer BS2 may include glass and/or a synthetic resin film. The synthetic resin layer may include a thermosetting resin. In embodiments, the synthetic resin layer may be a polyimide-based resin layer, and the material thereof is not particularly limited. The synthetic resin layer may include at least any one of an acrylic-based resin, a methacrylic-based resin, polyisoprene, a vinyl-based resin, an epoxy-based resin, a urethane-based resin, a cellulose-based resin, a siloxane-based resin, a polyamide-based resin, or a perylene-based resin. In embodiments, the second base layer BS2 may include a glass substrate, a metal substrate, and/or an organic/inorganic composite material substrate.

The color filter layer CFL is below the second base layer BS2. The color filter layer CFL may include color filters CF1, CF2, and CF3. The color filter layer CFL may include a first color filter CF1 that transmits a second color light, a second color filter CF2 that transmits a third color light, and a third color filter CF3 that transmits a first color light. For example, the first color filter CF1 may be a red color filter, the second color filter CF2 may be a green color filter, and the third color filter CF3 may be a blue color filter. The first color filter CF1 and the second color filter CF2 may be yellow color filters. The first color filter CF1 and the second color filter CF2 may not be separated from each other and may be provided as one integrated unit.

The first color filter CF1 may enhance color purity by transmitting only light of a partial wavelength range of the second color light, for example, light of the central wavelength range thereof. The second color filter CF2 may enhance color purity by transmitting only light of a partial wavelength range of the third color light, for example, light of the central wavelength range thereof. The third color filter CF3 may enhance color purity by transmitting only light of a partial wavelength range of the first color light, for example, light of the central wavelength range thereof.

Each of the color filters CF1, CF2, and CF3 may include a polymer photosensitive resin and a pigment and/or dye. The first color filter CF1 may include a red pigment and/or dye, the second color filter CF2 may include a green pigment and/or dye, and the third color filter CF3 may include a blue pigment and/or dye. Embodiments of the present disclosure are not limited thereto, and the third color filter CF3 may not include a pigment or dye. The third color filter CF3 may include a polymer photosensitive resin and may not include a pigment or dye. The third color filter CF3 may be transparent. The third color filter CF3 may be a transparent photosensitive resin.

The first to third color filters CF1, CF2, and CF3 may be provided to correspond to the first pixel region PXA-R, the second pixel region PXA-G, and the third pixel region PXA-B, respectively. In embodiments, the first to third color filters CF1, CF2, and CF3 may be provided to respectively correspond to first to third light control units CCP1, CCP2, and CCP3, which will be further described herein.

A plurality of color filters CF1, CF2, and CF3 that transmit light of different colors may be provided to overlap each other so as to correspond to the peripheral region NPXA between the pixel regions PXA-R, PXA-G, and PXA-B. The plurality of color filters CF1, CF2, and CF3 may be provided to overlap each other in the third direction DR3, which is the thickness direction. A region in which the plurality of color filters CF1, CF2, and CF3 are provided to overlap each other may define boundaries between adjacent light-emitting regions PXA-R, PXA-G, and PXA-B.

In embodiments, the color filter layer CFL may include a light blocking portion that defines boundaries between adjacent color filters CF1, CF2, and CF3. The light blocking portion may be formed of a blue color filter and/or include an organic and/or inorganic light blocking material including a black pigment and/or black dye.

The color filter layer CFL may further include a low refractive layer LR. The low refractive layer LR may be below the color filters CF1, CF2, and CF3. The low refractive layer LR may be on the light control layer CCL. The low refractive layer LR may be between the light control layer CCL and the color filters CF1, CF2, and CF3 and function as an optical functional layer to increase light extraction efficiency and/or prevent or reduce entrance of reflected light to the light control layer CCL. The low refractive layer LR may have a lower refractive index than an adjacent layer.

The low refractive layer LR may include an organic film. For example, the low refractive layer LR may be formed by including a polymer resin, inorganic particles, and/or the like. The low refractive layer LR may further include hollow particles and/or voids dispersed in the organic film, and the refractive index of the low refractive layer LR may be adjusted according to the ratio of the hollow particles and/or the voids.

The low refractive layer LR may be composed of a single layer or a plurality of layers. As illustrated in FIG. 5, the low refractive layer LR may be composed of a single layer.

The color filter layer CFL may further include a color filter capping layer CAP-CF. The color filter capping layer CAP-CF may be below the low refractive layer LR. The color filter capping layer CAP-CF may serve to prevent or reduce penetration of moisture and/or oxygen. The color filter capping layer CAP-CF may block or reduce exposure of the color filters CF1, CF2, and CF3 and/or the low refractive layer LR to moisture/oxygen.

The color filter capping layer CAP-CF may include an inorganic film. For example, the color filter capping layer CAP-CF may be formed by including silicon nitride, aluminum nitride, zirconium nitride, titanium nitride, hafnium nitride, tantalum nitride, silicon oxide, aluminum oxide, titanium oxide, tin oxide, cerium oxide, and silicon oxynitride, and/or a metal thin film having a secured light transmittance. However, embodiments of the present disclosure are not limited thereto.

The light control layer CCL may be below the color filter layer CFL. The light control layer CCL may be provided at the lowermost portion of the light conversion panel OP.

The light control layer CCL may include a division pattern BMP and light control units CCP1, CCP2, and CCP3. On a plane, the division pattern BMP may overlap the peripheral region NPXA. The light control units CCP1, CCP2, and CCP3 included in the light control layer CCL may be spaced apart from each other. The light control units CCP1, CCP2, and CCP3 may be spaced apart from each other by the division pattern BMP. The light control units CCP1, CCP2, and CCP3 may be provided within openings BW-OH1, BW-OH2, and BW-OH3 defined in the division pattern BMP. However, embodiments of the present disclosure are not limited thereto, and the edges of the light control units CCP1, CCP2, and CCP3 may overlap at least a portion of the division pattern BMP.

The division pattern BMP may include a material having a transmittance below a set value. For example, the division pattern BMP may include a light blocking material and a black coloring agent. The division pattern BMP may include a black dye and/or black pigment mixed in a base resin. For example, the black coloring agent of the division pattern BMP may include carbon black, a metal such as chromium, and/or an oxide thereof. For example, the division pattern BMP may include at least any one of propylene glycol methyl ether acetate, 3-methoxy-n-butyl acetate, acrylate monomer, acrylic monomer, organic pigment, or acrylate ester.

The light control units CCP1, CCP2, and CCP3 may convert the wavelength of source light provided from the light-emitting element layer EDL or transmit the provided source light without converting the wavelength thereof. The light control units CCP1, CCP2, and CCP3 may be formed through an inkjet process. A liquid ink composition may be provided in the openings BW-OH1, BW-OH2, and BW-OH3, and the provided ink composition may be polymerized through a thermal curing process and/or a light curing process to form the light control units CCP1, CCP2, and CCP3. For example, the shapes of the openings BW-OH1, BW-OH2, and BW-OH3 may correspond to the shapes of the light control units CCP1, CCP2, and CCP3.

The light control layer CCL may include a first light control unit CCP1 including a first quantum dot that converts the first color light provided from the light-emitting element OLED into the second color light, a second light control unit CCP2 including a second quantum dot that converts the first color light into the third color light, and a third light control unit CCP3 that transmits the first color light. The first light control unit CCP1 may provide red light which is the second color light, and the second light control unit CCP2 may provide green light which is the third color light. The third light control unit CCP3 may transmit and provide blue light which is the first color light provided from the light-emitting element OLED. For example, the first quantum dot may be a red quantum dot and the second quantum dot may be a green quantum dot.

A quantum dot refers to a crystal of a semiconductor compound. Because an energy band gap may be controlled by adjusting the size of the quantum dot or the ratio of elements in the quantum dot, light of various suitable wavelengths may be obtained. For example, the diameter of the quantum dot may be between about 1 nm and about 10 nm. Therefore, by using quantum dots of different sizes and/or quantum dots having different elemental ratios, it is possible to implement a light-emitting element configured to emit light at various suitable wavelengths. For example, the quantum dots may be implemented so as to emit red light, green light, or blue light. In embodiments, the quantum dots may be configured to emit white light by combining light of various suitable colors.

The quantum dots may be synthesized through a wet chemical process, a metal organic chemical vapor deposition process, a molecular beam epitaxy process, and/or a process similar thereto. The wet chemical process is a method of growing quantum dot particle crystals after mixing an organic solvent and a precursor material. When the crystals grow, the organic solvent may naturally act as a dispersant coordinated on the surface of the quantum dot crystals and control the growth of the crystals. Therefore, the wet chemical process may be easier than vapor deposition methods such as the metal organic chemical vapor deposition process or the molecular beam epitaxy process and control the growth of the quantum dot particles through a low-cost process.

The quantum dot may have a single structure or a core-shell dual structure in which the concentration of each element included in the quantum dot is uniform (e.g., substantially uniform). For example, a material included in a core and a material included in a shell may be different from each other. The shell of the quantum dot may serve as a protective layer to maintain semiconductor properties by preventing or reducing chemical modification of the core and/or as a filling layer for imparting electrophoretic properties to the quantum dot. The shell may have a single layer or a plurality of layers. The core/shell structure may have a concentration gradient in which the concentration of elements present in the shell decreases along a direction toward the core.

The core of the quantum dot may be selected from a group II-VI compound, a group III-VI compound, a group I-III-VI compound, a group III-V compound, a group III-II-V compound, a group IV-VI compound, a group IV element, a group IV compound, and combinations thereof.

The group II-VI compound may be selected from the group consisting of: a binary compound selected from the group consisting of CdSe, CdTe, CdS, ZnS, ZnSe, ZnTe, ZnO, HgS, HgSe, HgTe, MgSe, MgS, and mixtures thereof; a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and mixtures thereof; and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, and mixtures thereof.

The group III-VI compound may include a binary compound such as In₂S₃ and/or In₂Se₃, a ternary compound such as InGaS₃ and/or InGaSe₃, or any combinations thereof.

The group I-III-VI compound may be selected from a ternary compound selected from the group consisting of AgInS, AgInS₂, CuInS, CuInS₂, AgGaS₂, CuGaS₂ CuGaO₂, AgGaO₂, AgAlO_{2,} and mixtures thereof, and/or a quaternary compound such as AgInGaS₂, and CuInGaS₂.

The group III-V compound may be selected from the group consisting of: a binary compound selected from the group consisting of GaN, GaP, GaAs, GaSb, AlN, AlP, AlAs, AlSb, InN, InP, InAs, InSb, and mixtures thereof; a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and mixtures thereof; and a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and mixtures thereof. The group III-V compound may further include a group II metal. For example, InZnP and/or the like may be selected as a group III-II-V compound.

The group IV-VI compound may be selected from the group consisting of: a binary compound selected from the group consisting of SnS, SnSe, SnTe, PbS, PbSe, PbTe, and mixtures thereof; a ternary compound selected from the group consisting of SnSeS, SnSeTe, SnSTe, PbSeS, PbSeTe, PbSTe, SnPbS, SnPbSe, SnPbTe, and mixtures thereof; and a quaternary compound selected from the group consisting of SnPbSSe, SnPbSeTe, SnPbSTe, and mixtures thereof. The group IV element may be selected from the group consisting of Si, Ge, and mixtures thereof. The group IV compound may be a binary compound selected from the group consisting of SiC, SiGe, and mixtures thereof.

The group IV element or compound may include single-element compounds such as Si and/or Ge; binary compounds such as SiC and/or SiGe; or any combination thereof.

In embodiments, each element included in multi-element compounds, such as the binary compounds, the ternary compounds, and the quaternary compounds, may be present in a particle at a uniform or non-uniform concentration. For example, the above chemical formulas may mean types of elements included in the compounds, and the ratios of elements in the compounds may be different from each other. For example, AgInGaS₂ may mean AgInₓGa₁₋ₓS₂ (x is a real number between 0 and 1)

The shell of the quantum dot may include a metal and/or non-metal oxide, a semiconductor compound, or a combination thereof.

For example, the metal and/or non-metal oxide may include a binary compound such as SiO₂, Al2O₃, TiO₂, ZnO, MnO, Mn₂O₃, Mn₃O₄, CuO, FeO, Fe₂O₃, Fe₃O₄, CoO, Co₃O₄, and/or NiO, and/or a ternary compound such as MgAl₂O₄, CoFe₂O₄, NiFe₂O₄, and/or CoMn₂O₄, but embodiments of the present disclosure are not limited thereto.

In embodiments, examples of the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, and the like, but embodiments of the present disclosure are not limited thereto.

The quantum dot may have a full width of half maximum (FWHM) of a light-emitting wavelength spectrum of about 45 nm or less, about 40 nm or less, or, for example, about 30 nm or less, and within those ranges, it is possible to improve color purity and/or color reproducibility. In embodiments, because light emitted through the quantum dot is emitted in all (e.g., substantially all) directions, a wide viewing angle may be improved.

The shape of the quantum dot is not particularly limited to those generally used in the art, but, for example, a shape such as a spherical, pyramidal, multi-armed, and/or cubic nanoparticle, nanotube, nanowire, nanofiber, and/or nanoplate particle may be used.

As described above, the color of light to be emitted may be controlled according to the particle size of the quantum dot, and accordingly, the quantum dot may have various suitable light-emitting colors such as blue, red, and green. The smaller the particle size of the quantum dot, the shorter the wavelength range of light the quantum dot may emit. For example, in quantum dots having a same core, the particle size of the quantum dots that emit green light may be smaller than the particle size of the quantum dots that emit red light. In embodiments, in quantum dots having a same core, the particle size of the quantum dots that emit blue light may be smaller than the particle size of the quantum dots that emit green light. However, embodiments of the present disclosure are not limited thereto, and even in quantum dots having a same core, the particle size may be adjusted according to a shell-forming material and a shell thickness. When the quantum dots have various suitable light-emitting colors such as blue, red, and green, the quantum dots having different light-emitting colors may have different core materials.

The light control layer CCL may further include a scatterer (e.g., a light scatterer). The first light control unit CCP1 may include a first quantum dot and a scatterer (e.g., a light scatterer), the second light control unit CCP2 may include a second quantum dot and a scatterer (e.g., a light scatterer), and the third light control unit CCP3 may not include a quantum dot and may include a scatterer (e.g., a light scatterer).

The scatterer may be an inorganic particle. For example, the scatterer may include at least one of TiO₂, ZnO, Al₂O₃, SiO₂, or hollow silica. The scatterer may include any one selected from TiO₂, ZnO, Al₂O₃, SiO₂, and hollow silica, or may be a mixture of two or more materials selected from TiO₂, ZnO, Al₂O₃, SiO₂, and hollow silica.

Each of the first light control unit CCP1, the second light control unit CCP2, and the third light control unit CCP3 may further include a base resin that disperses quantum dots and scatterers (e.g., light scatterers). In an embodiment of the present disclosure, the first light control unit CCP1 may include first quantum dots and scatterers (e.g., light scatterers) dispersed in the base resin, the second light control unit CCP2 may include second quantum dots and scatterers (e.g., light scatterers) dispersed in the base resin, and the third light control unit CCP3 may include scatterers (e.g., light scatterers) dispersed in the base resin.

The base resin is a medium, in which the quantum dots and the scatterers are dispersed, and may be made of various suitable resin compositions, generally referred to as binders. For example, the base resin may be an acrylic-based resin, a urethane-based resin, a silicone-based resin, an epoxy-based resin, and/or the like. The base resin may be a transparent resin.

The light control layer CCL may further include a quantum dot capping layer CAP-QD below the light control units CCP1, CCP2, and CCP3. The quantum dot capping layer CAP-QD may serve to prevent or reduce penetration of moisture and/or oxygen. The quantum dot capping layer CAP-QD may be below the light control units CCP1, CCP2, and CCP3 and block or reduce exposure of the light control units CCP1, CCP2, and CCP3 to moisture/oxygen. In embodiments, the quantum dot capping layer CAP-QD may cover not only one surface of each of the light control units CCP1, CCP2, and CCP3 but also one surface of the division pattern BMP.

The quantum dot capping layer CAP-QD may include an inorganic film. For example, the quantum dot capping layer CAP-QD may be formed by including silicon nitride, aluminum nitride, zirconium nitride, titanium nitride, hafnium nitride, tantalum nitride, silicon oxide, aluminum oxide, titanium oxide, tin oxide, cerium oxide, and silicon oxynitride, and/or a metal thin film having a set or secured light transmittance.

The display device DD may further include a filling layer FML between the display panel DP and the light conversion panel OP. The filling layer FML may be used to fill a space between the display panel DP and the light conversion panel OP. The filling layer FML may function as a buffer between the display panel DP and the light conversion panel OP. The filling layer FML may function as a shock absorber and increase the strength of the display device DD. The filled layer FML may be formed from a filling resin including a polymer resin. For example, the filling layer FML may include a filling layer resin including an acrylic-based resin, an epoxy-based resin, and/or the like.

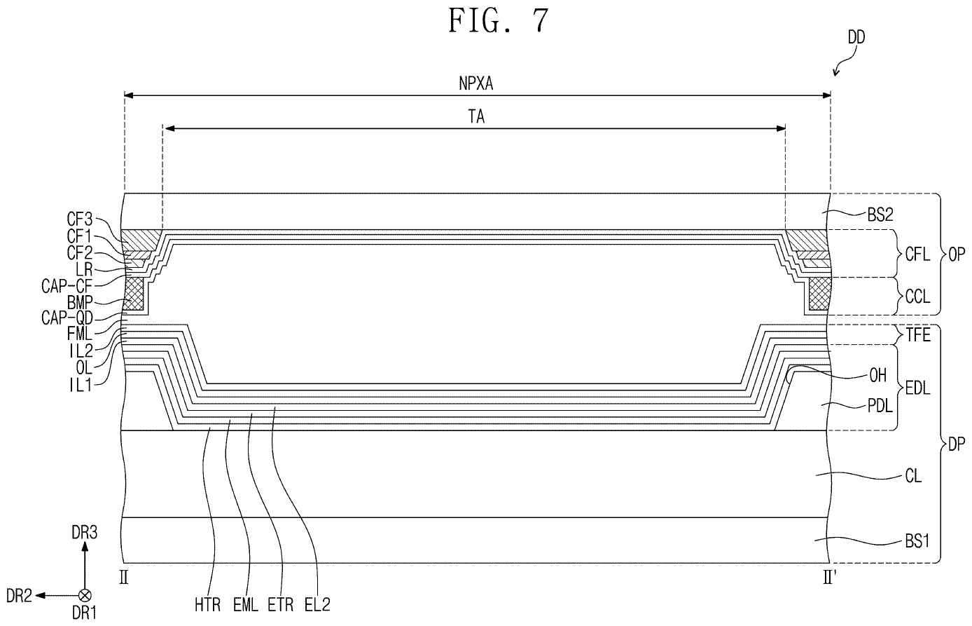

FIG. 7 is a cross-sectional view of the display device DD according to an embodiment of the present disclosure.

FIG. 7 illustrates a cross section corresponding to line II-II′ illustrated in FIG. 4A. The description mentioned above may be equally applied to the same configuration as illustrated in FIG. 5.

The color filters CF1, CF2, and CF3 may not overlap the transmission region TA. The color filters CF1, CF2, and CF3 may include an opening substantially corresponding to the transmission region TA.

The low refractive layer LR may be below the color filters CF1, CF2, and CF3. The low refractive layer LR may be directly under the color filters CF1, CF2, and CF3 and cover the lower surfaces of the color filters CF1, CF2, and CF3. In embodiments, the low refractive layer LR may be below the second base layer BS2. For example, in the transmission region TA in which the color filters CF1, CF2, and CF3 are not provided, the low refractive layer LR may be directly under the second base layer BS2. Without being limited thereto, however, the low refractive layer LR may not be provided in the transmission region TA.

The low refractive layer LR may include an organic film. For example, the low refractive layer LR may be formed by including a polymer resin and inorganic particles. The low refractive layer LR may further include hollow particles and/or voids dispersed in the organic film.

The color filter capping layer CAP-CF may be below the low refractive layer LR. The color filter capping layer CAP-CF may include an inorganic film. For example, the color filter capping layer CAP-CF may be made of silicon nitride, aluminum nitride, zirconium nitride, titanium nitride, hafnium nitride, tantalum nitride, silicon oxide, aluminum oxide, titanium oxide, tin oxide, cerium oxide, and/or silicon oxynitride, and/or a metal thin film having a set or secured light transmittance. However, embodiments of the present disclosure are not limited thereto.

The division pattern BMP may be below the color filter capping layer CAP-CF. The division pattern BMP may be provided to non-overlap the transmission region TA. The division pattern BMP may surround the transmission region TA on a plane.

The quantum dot capping layer CAP-QD may be below the division pattern BMP. In the transmission region TA, the quantum dot capping layer CAP-QD may be below the color filter capping layer CAP-CF. In the transmission region TA, the quantum dot capping layer CAP-QD may be directly under the color filter capping layer CAP-CF.

The quantum dot capping layer CAP-QD may include an inorganic film. For example, the quantum dot capping layer CAP-QD may be formed by including silicon nitride, aluminum nitride, zirconium nitride, titanium nitride, hafnium nitride, tantalum nitride, silicon oxide, aluminum oxide, titanium oxide, tin oxide, cerium oxide, and/or silicon oxynitride, and/or a metal thin film having a set or secured light transmittance.

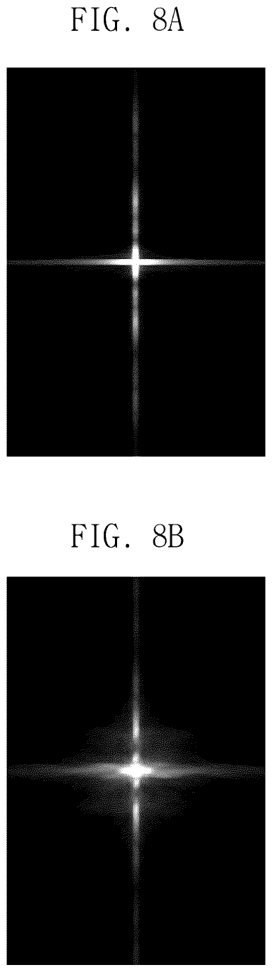

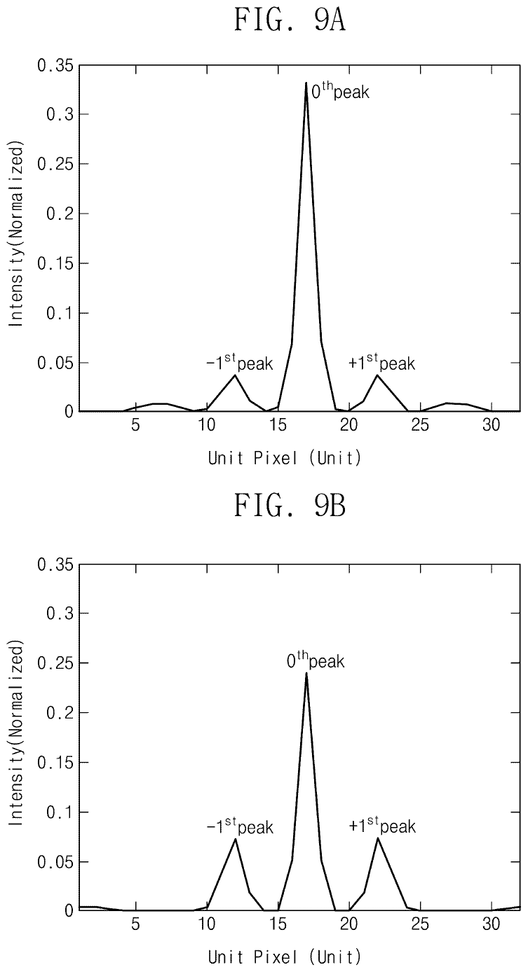

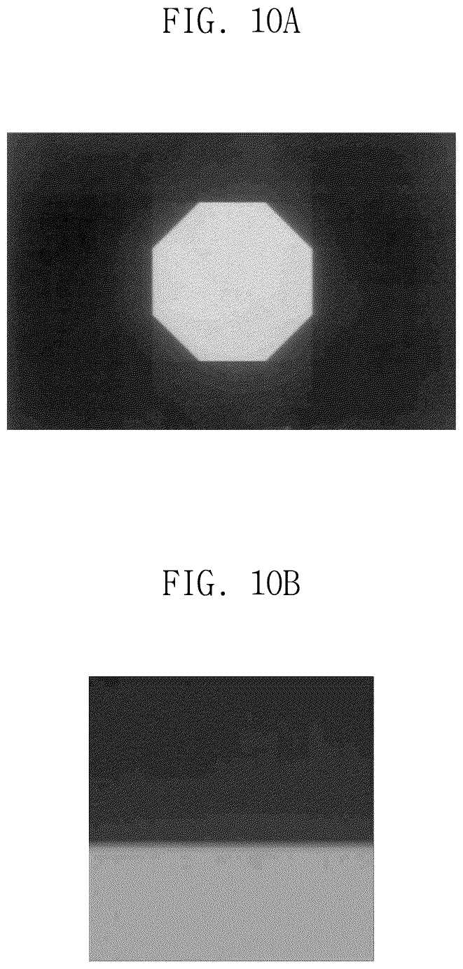

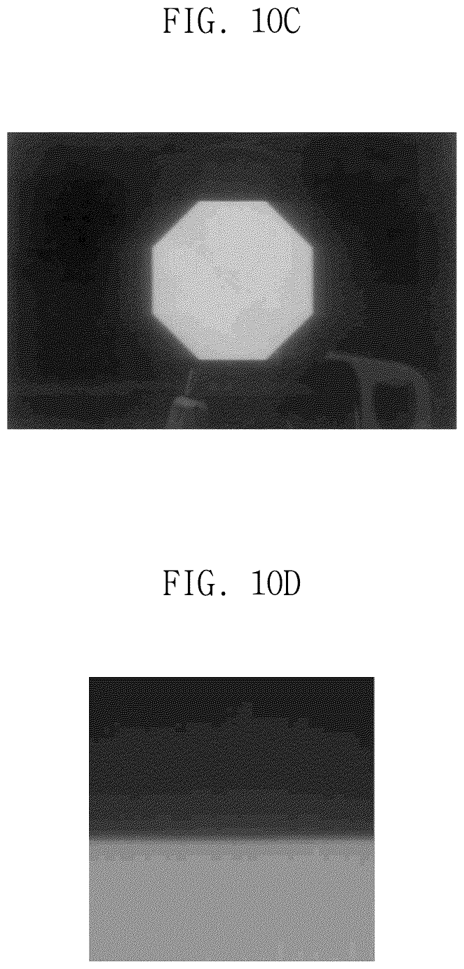

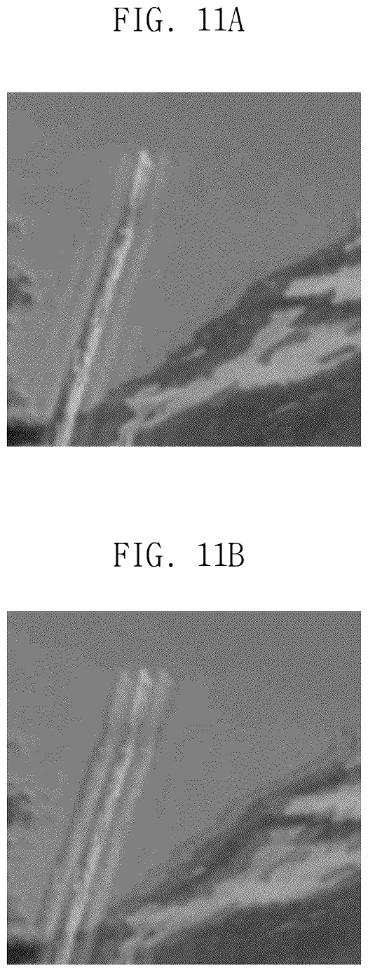

FIGS. 8A and 8B are clarity evaluation images according to an embodiment of the present disclosure and a comparative embodiment of the present disclosure, respectively. FIGS. 9A and 9B are clarity evaluation graphs according to an embodiment of the present disclosure and a comparative embodiment of the present disclosure, respectively. FIGS. 10A and 10B are a clarity evaluation photograph and an enlarged photograph thereof, respectively, according to an embodiment of the present disclosure. FIGS. 10C and 10D are a clarity evaluation photograph and an enlarged photograph thereof, respectively, according to a comparative embodiment of the present disclosure. FIGS. 11A and 11B are images evaluating diffraction characteristics according to an embodiment of the present disclosure and a comparative embodiment of the present disclosure, respectively.

FIGS. 8A, 9A, 10A, 10B, and 11A respectively show the results of evaluating the clarity of transmitted light when an aperture ratio is about 66.3%. FIGS. 8B, 9B, 10C, 10D, and 11B respectively show the results of evaluating the clarity of transmitted light when the aperture ratio is about 47.5%. In embodiments, the aperture ratio may mean an area A_{TA} (see FIG. 4A) of the transmission region TA (see FIG. 4A), based on the area of the unit pixel PXU (see FIG. 4A).

Each of FIGS. 8A and 8B shows the measurement of a shape (PSF: point spread function) of one point light source being transmitted. Referring to FIGS. 8A and 8B together, it can be seen that the transmitted light is clearer in the embodiment having an aperture ratio of about 66.3% than in the comparative embodiment having an aperture ratio of about 47.5%.

FIG. 9A is a graph showing the result of measuring the intensities of a central peak (0th peak) and first peaks occurring on the left and right of the central peak for the image of FIG. 8A. FIG. 9B is a graph showing the result of measuring the intensities of a central peak and first peaks for the image of FIG. 9A. The intensities of the peaks were measured across 30 unit pixels PXU (see FIG. 4A), and the intensities are shown as normalized values, based on the total area of the graph.

Referring to FIG. 9A, the ratio (ZOR: Zero order ratio, %) of the energy of the central peak, based on the total energy, is calculated to be about 68%. Referring to FIG. 9B, the ratio of the energy of the central peak, based on the total energy, is calculated to be about 49.7%. It can be seen that the ratio of the energy of the central peak is higher when the aperture ratio is about 66.3% than when the aperture ratio is about 47.5%, and therefore the transmitted light is much clearer.

Referring to FIGS. 10A and 10C together, it can be seen that the transmitted image of an octagonal light source is clearer in the embodiment having an aperture ratio of about 66.3% than in the comparative embodiment with an aperture ratio of about 47.5%. FIG. 10B is an enlarged image in which the boundary of the transmitted image of the octagonal light source of FIG. 10A is enlarged, and FIG. 10D is an enlarged image in which the boundary of the transmitted image of the octagonal light source of FIG. 10C is enlarged. Comparing contrast sensitivity indexes with respect to FIGS. 10A to 10D, the contrast sensitivity indexes were measured to be 2.6 in the embodiment having an aperture ratio of about 66.3% and 3.9 in the comparative embodiment having an aperture ratio of about 47.5%. The contrast sensitivity index is one of the values by which clarity can be evaluated, and the lower the value, the clearer it is.

Referring to FIGS. 11A and 11B together, it can be seen that a double image is significantly reduced in the embodiment having an aperture ratio of about 66.3% when compared to the comparative embodiment with an aperture ratio of about 47.5%.

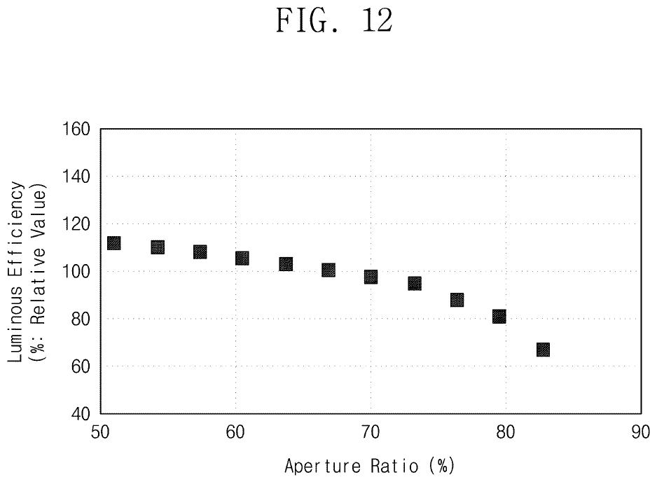

FIG. 12 is a graph showing the results of evaluating the luminous efficiency of the display device according to aperture ratios.

Referring to FIG. 12, as the aperture ratios increase, the luminous efficiency tends to decrease proportionally. However, when the aperture ratio exceeds about 73%, it can be seen that the luminous efficiency is significantly lowered.

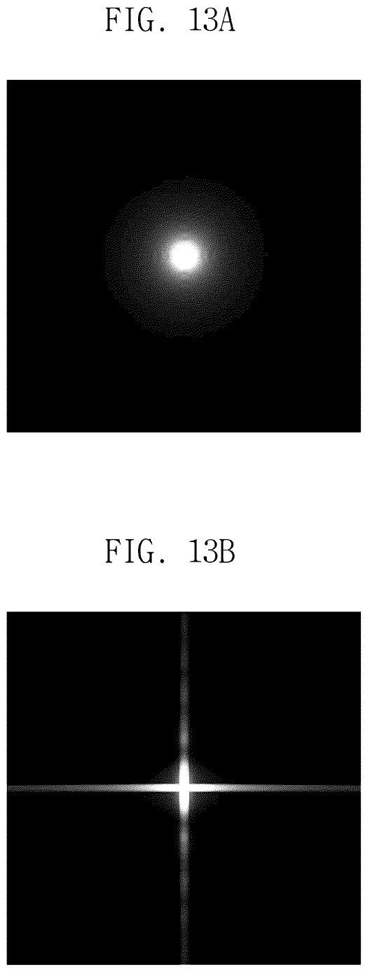

FIGS. 13A and 13B are clarity evaluation images according to an embodiment of the present disclosure and a comparative embodiment of the present disclosure, respectively.

FIG. 13A shows the result of evaluating the clarity of transmitted light when the planar shape of the transmission region TA (see FIG. 4A) is circular. FIG. 13B shows the result of evaluating the clarity of transmitted light when the planar shape of the transmission region is tetragonal.

Each of FIGS. 13A and 13B shows the measurement of the shape (PSF) of one point light source being transmitted. Referring to FIGS. 13A and 13B together, it can be seen that the diffraction characteristics of transmitted light are further improved in the embodiment in which the planar shape of the transmission region is circular when compared to the comparative embodiment in which the planar shape of the transmission region is tetragonal. For example, referring to FIG. 13A, it can be seen that a clear light source is observed without any diffraction tail occurring in the transmitted light.

Because the area of the transmission region according to an embodiment of the present disclosure is between about 50% and about 73%, based on the unit pixel, excellent luminous efficiency may be maintained while improving the clarity of transmitted light. In embodiments, as the planar shape of the transmission region is circular, the diffraction characteristics are improved, thereby being able to improve the clarity of the transmitted light.

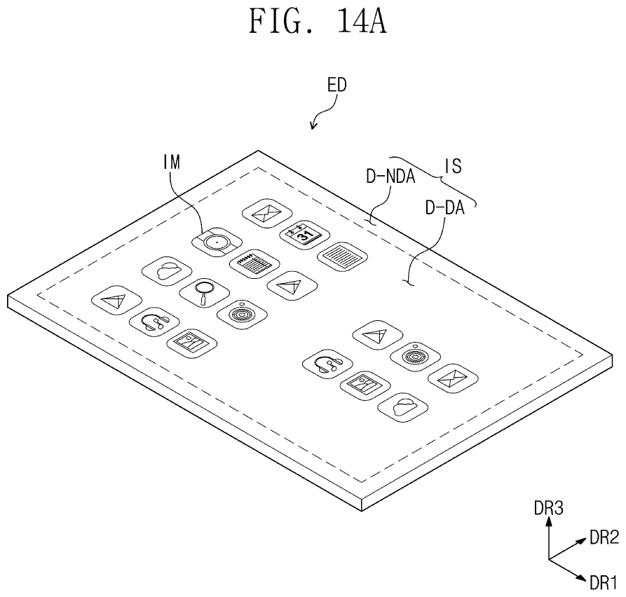

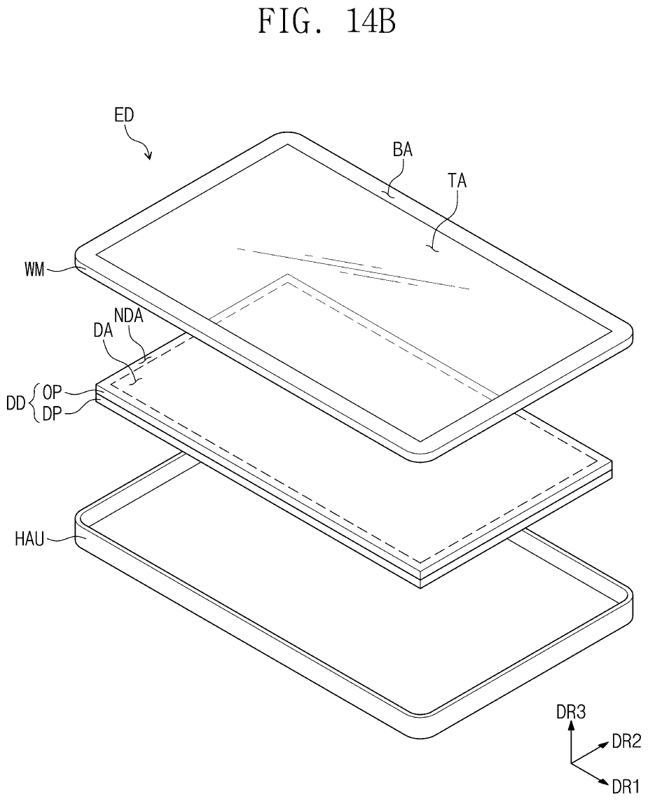

FIG. 14A is a perspective view of an electronic device according to an embodiment of the disclosure. FIG. 14B is an exploded perspective view of the electronic device according to an embodiment of the disclosure.

The electronic device ED may be activated according to an electrical signal and display an image. The electronic device ED may include various suitable embodiments, and for example, the electronic device ED may include large devices such as televisions and external billboards, and small and medium-sized devices such as monitors, mobile phones, tablet computers, navigation systems, and game machines. The embodiments of the electronic device ED disclosed herein are examples and the present disclosure is not limited to any one embodiment as long as they do not depart from the spirit or scope of the present disclosure.

The electronic device ED may display an image IM in a third direction DR3 through a display surface IS parallel to a plane defined by a first direction DR1 and a second direction DR2. The third direction DR3 may be parallel to a normal direction of the display surface IS. The display surface IS on which the image IM is displayed may correspond to the front surface of the electronic device ED. The image IM may include a still image as well as a dynamic image (e.g., a moving image). FIG. 14A illustrates icon images as an example of the image IM.

FIG. 14A illustrates, as an example, the electronic device ED having a flat display surface IS. However, the shape of the display surface IS of the electronic device ED is not limited thereto and may be a curved shape or a three-dimensional shape.

The electronic device ED may be flexible. The term “flexible” refers to a property of being bendable, and a flexible structure may include everything from a completely foldable structure to a structure that can be bent to the level of several nanometers. For example, the flexible electronic device ED may include a curved display device and/or a foldable display device. However, without being limited thereto, the electronic device ED may be a rigid one.

The display surface IS of the electronic device ED may include a display region D-DA and a peripheral region D-NDA. An image IM may be displayed in the display region D-DA. A user may visually recognize the image IM through the display region D-DA. In an embodiment of the present disclosure illustrated in FIG. 14A, the display region D-DA is illustrated as having a rectangular shape, but this is illustrated as an example, and the display region D-DA may have various suitable shapes.

The peripheral region D-NDA may be a non-display portion that does not display an image IM. The peripheral region D-NDA may correspond to a portion that has a color and blocks light. The peripheral region D-NDA may be adjacent to the display region D-DA. For example, the peripheral region D-NDA may be provided outside at least one side of the display region D-DA, and the peripheral region D-NDA may surround the display region D-DA. However, this is illustrated as an example, and the peripheral region D-NDA may be adjacent only to one side of the display region D-DA or may be on a side surface other than the front surface of the electronic device ED, and without being limited thereto, the peripheral region D-NDA may be omitted.

The electronic device ED according to an embodiment of the present disclosure may sense an external input applied from the outside. The external input may have various suitable forms such as pressure, temperature, and light provided from the outside. The external input may include an input applied at a place close to the electronic device ED (e.g., hovering) as well as an input that contacts the electronic device ED (e.g., a touch by a user's hand and/or a pen).

Referring to FIG. 14B, the electronic device ED may include a window WM, a display device DD, and a housing HAU, wherein the display device DD may include a display panel DP and a light conversion panel OP. The window WM and the housing HAU may be coupled to each other to define the appearance of the electronic device ED and may provide an internal space for accommodating the elements of the electronic device ED such as the display device DD.

The window WM may be on the display device DD. The window WM may protect the display device DD from an external impact. The front surface of the window WM may correspond to the aforementioned display surface IS of the electronic device ED. The front surface of the window WM may include a transmission region TA and a bezel region BA.

The transmission region TA of the window WM may be an optically transparent region. The window WM may transmit an image provided by the display device DD through the transmission region TA, and a user may visually recognize the corresponding image. The transmission region TA may correspond to the display region D-DA of the electronic device ED.

The window WM may include an optically transparent insulating material (e.g., an optically transparent electrically insulating material). For example, the window WM may include glass, sapphire, and/or plastic. The window WM may have a single-layered or multi-layered structure. The window WM may further include functional layers such as an anti-fingerprint layer, a phase control layer, and a hard coating layer which are on an optically transparent substrate.

The bezel region BA of the window WM may be provided as a region on which a material having a color is deposited, coated, and/or printed. The bezel region BA of the window WM may prevent a configuration of the display device DD, which is provided to overlap the bezel region BA, from being visually recognized from the outside (or reduce an occurrence, likelihood, or degree thereof). The bezel region BA may correspond to the peripheral region D-NDA of the electronic device ED.

The display device DD may display an image according to an electrical signal. The display device DD may include a display region DA and a non-display region NDA adjacent to the display region DA.

The display region DA may be a portion corresponding to the display region D-DA of the electronic device ED. The display region DA may be activated according to an electrical signal. The display region DA may be a region configured to display an image provided by the display device DD. The display region DA of the display device DD may correspond to the aforementioned transmission region TA. In this specification, the expression “a region/portion corresponds to another region/portion” means that “they overlap each other”, but the expression is not limited to having a same area and/or a same shape. An image displayed on the display region DA may be visually recognized from the outside through the transmission region TA.

The non-display region NDA may be adjacent to the display region DA. For example, the non-display region NDA may surround the display region DA. However, without being limited thereto, the non-display region NDA may be defined to have various suitable shapes. The non-display region NDA may correspond to the peripheral region D-NDA of the electronic device ED. The non-display region NDA may be a region in which a driving circuit or driving line configured to drive the display region DA, various suitable signal lines configured to provide electrical signals, and pads are provided. The non-display region NDA of the display module DM may correspond to the aforementioned bezel region BA. The elements of the display module DM provided in the non-display region NDA may be prevented from being visually recognized by the bezel region BA.

The housing HAU may be provided below and accommodate the display device DD. Because the housing HAU absorbs a shock applied from the outside and prevents or reduces entrance of foreign substances/moisture into the display device DD, the housing HAU may protect the display device DD. The housing HAU according to an embodiment of the present disclosure may be provided in a form in which a plurality of accommodation members are coupled to each other.

The display module DD may further include an input detection unit. The input detection unit may obtain the coordinate information of an external input applied from the outside of the electronic device ED. The input detection unit may be between the display panel DP and the light conversion panel OP. For example, the input detection unit may be directly on the display panel DP through a continuous process, or without being limited thereto, may be separately manufactured and attached to the display panel DP by an adhesive layer.

According to the foregoing, the display device of the present disclosure may provide improved clarity and diffraction characteristics of the transmitted light.

Although the above has been described with reference to example embodiments of the present disclosure, those skilled in the art or those of ordinary skill in the art will understand that various suitable modifications and changes can be made to the subject matter of the present disclosure within the scope that does not depart from the spirit and technical field of the present disclosure described in the appended claims, and equivalents thereof. Accordingly, the technical scope of the present disclosure should not be limited to the content described in the detailed description of the specification, but should be determined by the appended claims, and equivalents thereof.

What is claimed is:

1. A display device comprising:
a display region including a plurality of unit pixels; and
a non-display region adjacent to the display region,
wherein:
each of the plurality of unit pixels comprises at least one pixel region and a transmission region which is adjacent to the pixel region and through which external light is transmitted; and
for each of the plurality of unit pixels, a ratio of an area of the transmission region to an area of the unit pixel is between about 50% and about 73%.

2. The display device of claim 1, wherein a planar shape of the transmission region is oval.

3. The display device of claim 1, wherein a planar shape of the transmission region is circular.

4. The display device of claim 1, wherein each of the plurality of unit pixels comprises:
a first pixel region that emits a first light;
a second pixel region that emits a second light having a wavelength different from a wavelength of the first light; and
a third pixel region that emits a third light having a wavelength different from the wavelengths of the first light and the second light.

5. The display device of claim 4, wherein each of the first to third pixel regions is provided alternately with the transmission region along a first direction.

6. The display device of claim 5, wherein the first to third pixel regions are provided sequentially and alternately along a second direction perpendicular to the first direction.

7. The display device of claim 4, wherein each of the first and second pixel regions is provided alternately with the transmission region along a first direction.

8. The display device of claim 7, wherein each of the first and second pixel regions is provided alternately with the third pixel region along the first direction.

9. The display device of claim 7, wherein the first and second pixel regions are provided alternately along a second direction perpendicular to the first direction.

10. A display device comprising:
a display region comprising a plurality of unit pixels; and
a non-display region adjacent to the display region,
wherein each of the plurality of unit pixels comprises:
at least one pixel region; and
a transmission region which is adjacent to the pixel region and through which external light is transmitted,
wherein a planar shape of the transmission region is circular or oval.

11. The display device of claim 10, wherein, for each of the plurality of unit pixels, a ratio of an area of the transmission region to an area of the unit pixel is between about 50% and about 73%.

12. The display device of claim 10, wherein each of the plurality of unit pixels comprises:
a first pixel region that emits a first light;
a second pixel region that emits a second light having a wavelength different from a wavelength of the first light; and
a third pixel region that emits a third light having a wavelength different from the wavelengths of the first light and the second light.

13. The display device of claim 12, wherein each of the first to third pixel regions is provided alternately with the transmission region along a first direction.

14. The display device of claim 13, wherein the first to third pixel regions are provided sequentially and alternately along a second direction perpendicular to the first direction.

15. The display device of claim 12, wherein each of the first and second pixel regions is provided alternately with the transmission region along a first direction.

16. The display device of claim 15, wherein each of the first and second pixel regions is provided alternately with the third pixel region along the first direction.

17. The display device of claim 15, wherein the first and second pixel regions are provided alternately along a second direction perpendicular to the first direction.

18. An electronic device comprising:
a display device;
a window on the display device; and
a housing under the display device,
wherein the display device comprises:
a display panel comprising a unit pixel comprising a plurality of pixel regions and a transmission region adjacent to the plurality of pixel regions; and
a light conversion panel on the display panel,
wherein the light conversion panel comprises a color filter layer,
wherein:
the color filter layer comprises an opening defining the transmission region; and
a planar shape of the opening is circular or oval.

19. The electronic device of claim 18, wherein the plurality of pixel regions are provided alternately with the transmission region along a first direction.

20. The electronic device of claim 18, wherein, based on an area of the unit pixel, an area of the opening is between about 50% and about 73%.
